(19) United States
(12) Patent Application Publication
(10) Pub. No.: US 2025/0236470 A1
(43) Pub. Date: Jul. 24, 2025

(54) TRANSFER APPARATUS AND WAFER STORAGE CONTAINER CLEANING APPARATUS

(71) Applicant: SHIBAURA MECHATRONICS CORPORATION, Kanagawa (JP)

(72) Inventors: Yukinobu NISHIBE, Kanagawa (JP); Junji ISHIHARA, Kanagawa (JP); Hisaaki MIYASAKO, Kanagawa (JP)

(21) Appl. No.: 19/012,314

(22) Filed: Jan. 7, 2025

(30) Foreign Application Priority Data
Jan. 19, 2024 (JP) 2024-006553

(51) Int. Cl. B65G 47/90; B08B 9/08; B08B 9/093; G03F 7/00; H01L 21/677

(52) U.S. Cl. CPC B65G 47/90; B08B 9/0826; B08B 9/093; G03F 7/7075; H01L 21/6773; B08B 2209/08

(57) ABSTRACT

According to one embodiment, a transfer apparatus includes: a transfer robot transferring a shell of a wafer storage container to a placement table including a positioning member. The transfer robot includes a gripping unit with a pair of shell gripping claws that grips a flange of the shell, and a support member contactable with the shell at a different position from the flange. The support member supports the shell such that in a state where the flange is gripped by the shell gripping claws, and the placement target surface of the shell faces downward, the placement target surface has a posture placeable on the placement surface of the placement table via the positioning member. The transfer robot transfers the shell to the placement table in a state where the flange is gripped by the shell gripping claws, and the shell is supported by the support member.

### CROSS-REFERENCE TO RELATED APPLICATIONS

This application is based on and claims priority from Japanese Patent Application No. 2024-006553, filed on Jan. 19, 2024, with the Japan Patent Office, the disclosure of which is incorporated herein in its entirety by reference.

### TECHNICAL FIELD

The present disclosure relates to a transfer apparatus and a wafer storage container cleaning apparatus.

### BACKGROUND

Wafer storage containers such as front opening unified pods (FOUPs) are used to carry wafers, on which semiconductor elements are formed through various processing processes (e.g., resist coating, exposure/development, etching (film formation), resist removal, and cleaning), among processing processes. The wafer storage containers are transferred by a robot in a state where wafers are held in the wafer storage containers.

Each wafer storage container includes a wafer storage container body (hereinafter, referred to simply as the “body”) and a door, and a flange is provided on the body to be gripped by a robot. When a robot hand holds the body via the flange in a state where the opening of the body (the side of the wafer storage container on which the door is provided) faces downward, a portion of the flange may bend, and thus, the body may sag downward from the support point where the flange is held by the robot hand. In this case, when the robot grips the flange, the lower end of the body tilts with respect to the horizontal plane. When the robot transfers the body to place the body on, for example, a roughly horizontal stage in a state where the body tilts, the lower end of the body may not align with positioning pins provided on, for example, the stage, which may make it difficult to place the body.

In the case described above, processes stop to unload the wafer storage container, which deteriorates the process efficiency (see, e.g., Japanese Patent Laid-Open Publication No. 2005-109523).

### SUMMARY

The present disclosure provides a transfer apparatus and a wafer storage container cleaning apparatus, which may efficiently perform processes.

According to an aspect of the present disclosure, a transfer apparatus includes: a transfer robot that transfers a shell of a wafer storage container to a placement table including a positioning member. The transfer robot includes a gripping unit that grips the shell. The gripping unit includes a pair of shell gripping claws that grips a flange of the shell, and a support member contactable with the shell at a different position from the flange. A placement target surface of the shell crosses a surface of the shell on which the flange is provided. The support member is provided to support the shell such that in a state where the flange is gripped by the shell gripping claws, and the placement target surface of the shell faces downward, the placement target surface of the shell, before being placed on a placement surface of the placement table, has a posture placeable on the placement surface of the placement table via the positioning member. The transfer robot transfers the shell to the placement table in a state where the flange is gripped by the shell gripping claws, and the shell is supported by the support member.

According to another aspect of the present disclosure, a wafer storage container cleaning apparatus includes: the transfer apparatus according to claim 1; and a cleaning chamber including the placement table, and a cleaning nozzle that cleans the shell in a state where the shell is placed on the placement surface of the placement table.

According to the aspects of the present disclosure, it is possible to provide a transfer apparatus and a wafer storage container cleaning apparatus, which may efficiently perform processes.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a plan view illustrating an example of a schematic configuration of a wafer storage container cleaning apparatus according to a first embodiment.

FIG. 2 is a cross-sectional view of the wafer storage container cleaning apparatus according to the first embodiment, which is taken along the line X-X in FIG. 1.

FIG. 3 is a schematic view illustrating an example of a configuration of a transfer robot according to the first embodiment.

FIG. 4 is a plan view illustrating an example of a lock/unlock stage according to the first embodiment.

FIG. 5 is a cross-sectional view (side sectional view) taken along the line Y-Y in FIG. 4.

FIG. 6 is a plan view illustrating an example of a rotary table (placement table) provided in a cleaning chamber according to the first embodiment.

FIG. 7 is a view of a portion of the side surface of the rotary table according to the first embodiment.

FIG. 8 is a view illustrating an example of a state where a robot hand according to the first embodiment grips a flange and lifts a body in a case where no support member is provided.

FIG. 9 is a view illustrating an example of a state where the robot hand according to the first embodiment does not grip the flange and does not lift the body in the case where no support member is provided.

FIG. 10 is a side view of an example of a support member according to the first embodiment.

FIG. 11 is an enlarged view of a contact portion between the support member and the body according to the first embodiment.

### DESCRIPTION OF EMBODIMENTS

In the following detailed description, reference is made to the accompanying drawings which form a part hereof. The illustrative embodiments described in the detailed description, drawings, and claims are not meant to be limiting. Other embodiments may be utilized, and other changes may be made without departing from the spirit or scope of the subject matter presented herein.

Hereinafter, with reference to the accompanying drawings, embodiments of a transfer apparatus and a wafer storage container cleaning apparatus of the present disclosure are described in detail. The transfer apparatus and the wafer storage container cleaning apparatus of the present disclosure are not limited to the embodiments described herein below. Each embodiment and each modification thereof may be appropriately combined with each other in the scope that does not cause any inconsistency.

### First Embodiment

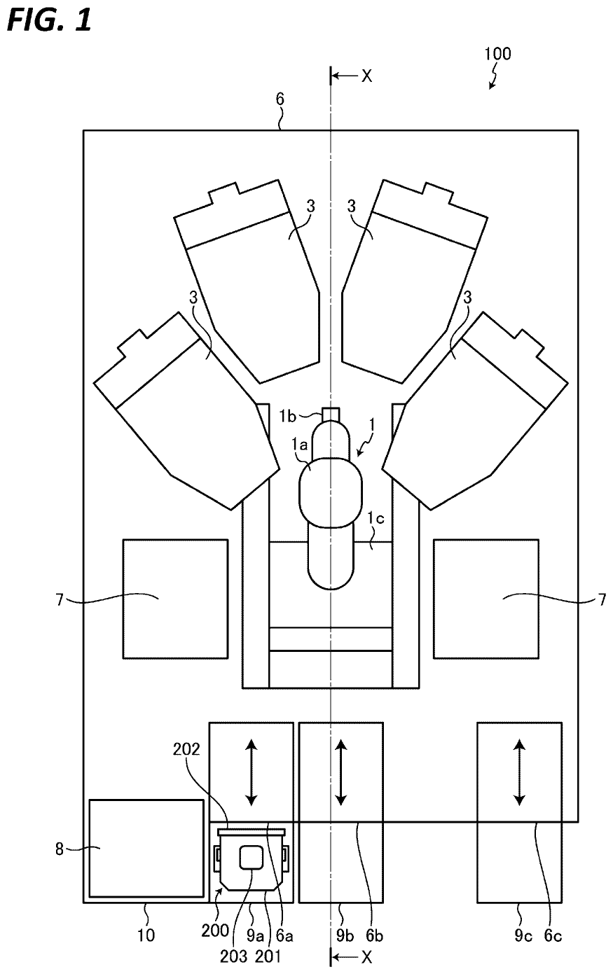

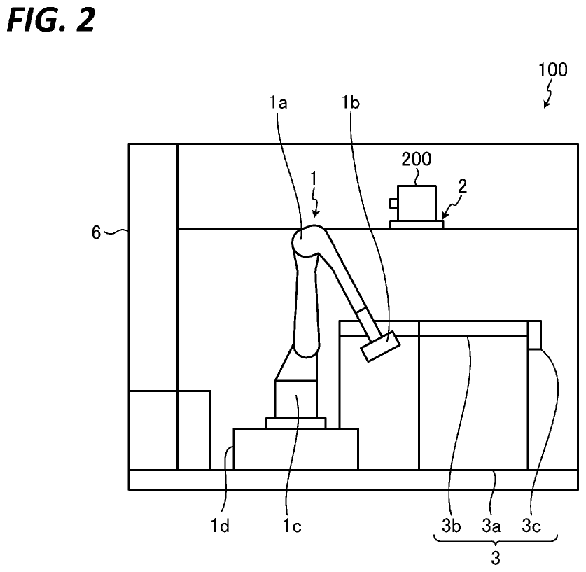

FIG. 1 is a plan view illustrating an example of a schematic configuration of a wafer storage container cleaning apparatus 100 according to a first embodiment. FIG. 2 is a cross-sectional view taken along the line X-X of FIG. 1. The wafer storage container cleaning apparatus 100 is provided in, for example, a plant for manufacturing semiconductor wafers, and cleans wafer storage containers. As illustrated in FIGS. 1 and 2, the wafer storage container cleaning apparatus 100 includes a transfer robot 1, a lock/unlock stage 2, a cleaning chamber 3, a vacuum processing chamber 7, a control unit 8, a first carry-in/out port 9a, a second carry-in/out port 9b, a third carry-in/out port 9c, an input interface 10, and a housing 6. In the present embodiment, the apparatus including the transfer robot 1 is referred to as a transfer apparatus.

In the present embodiment, a wafer storage container 200 is, for example, a FOUP or FOSB, and includes a shell (container body) 201 and a door (lid) 202. The shell 201 has a hexahedral shape in appearance. The shell 201 has a rectangular opening in one side thereof. Further, the shell 201 has a storage space for storing semiconductor wafers. The storage space is present on the inner side than the opening, and communicates with the opening. The door 202 may be locked/unlocked with respect to the shell 201, and is removably mounted in the opening of the shell 201. In a state where the door 202 is mounted in the opening of the shell 201, the end of the shell 201 forming the opening aligns with the face of the door 202 mounted in the shell 201. Further, a flange 203 is provided on the shell 201. For example, the shell 201 includes the flange 203 on another side thereof orthogonal to (crossing) the side where the opening is present. The flange 203 is a portion that is gripped (held) when the wafer storage container 200 is transferred by, for example, an overhead hoist transport (OHT) or a transfer robot 1, and formed in a square plate shape.

The transfer robot 1, the lock/unlock stage 2, the cleaning chamber 3, the vacuum processing chamber 7, and the control unit 8 are provided inside a housing 6. Meanwhile, the first carry-in/out port 9a, the second carry-in/out port 9b, and the third carry-in/out port 9c are provided across the inside and the outside of the housing 6.

The first carry-in/out port 9a carries the wafer storage container 200, which is a cleaning target, placed at the portion thereof outside the housing 6, into the housing 6.

For example, at the portion of the first carry-in/out port 9a outside the housing 6, the wafer storage container 200 that has been transferred in a state where the flange 203 is gripped by the OHT is placed. For example, as illustrated in FIG. 1, the wafer storage container 200 is placed at the first carry-in/out port 9a such that the door 202 of the wafer storage container 200 faces the housing 6. In this way, when the wafer storage container 200 is placed at the first carry-in/out port 9a, a shutter provided in the opening 6a of the housing 6 moves up. Accordingly, the wafer storage container 200 becomes ready to be carried into the housing 6 from the opening 6a. Then, the wafer storage container 200 slides in the direction toward the inside of the housing 6 by a slide device of the first carry-in/out port 9a, and is carried into the housing 6.

Further, the first carry-in/out port 9a carries the wafer storage container 200 placed at the portion of the first carry-in/out port 9a inside the housing 6 by the transfer robot 1 after being cleaned and vacuum-dried, to the outside of the housing 6.

For example, at the portion of the first carry-in/out port 9a inside the housing 6, the wafer storage container 200 of which the shell 201 and the door 202 are connected to each other on the lock/unlock stage 2 after the vacuum drying is transferred and placed by the transport robot 1. In this way, when the wafer storage container 200 is placed at the first carry-in/out port 9a, the shutter provided in the opening 6a of the housing 6 moves up. Accordingly, the wafer storage container 200 becomes ready to be carried to the outside of the housing 6 from the opening 6a. Then, the wafer storage container 200 slides in the direction toward the outside of the housing 6 by the slide device of the first carry in/out port 9a, and is carried to the outside of the housing 6.

Similarly to the first carry in/out port 9a, the second carry in/out port 9b may perform the carry-in/out of the wafer storage container 200 through the opening 6b of the housing 6. The third carry-in/out port 9c may also be configured to perform the carry-in/out of the wafer storage container 200 through the opening 6c of the housing 6 in the same manner as performed by the first carry-in/out port 9a.

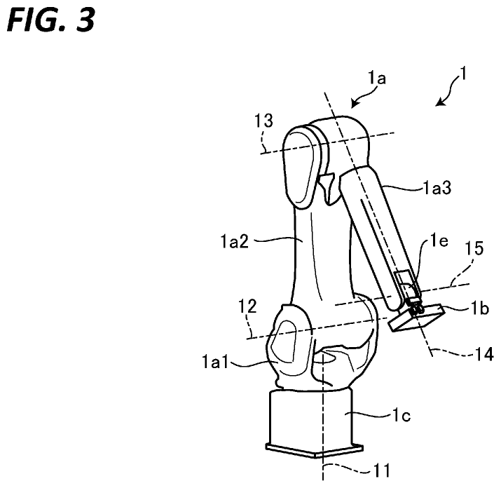

The transfer robot 1 is a vertical articulated robot, and transfers the wafer storage container 200 to each unit in a state of gripping the flange 203 of the wafer storage container 200. FIG. 3 is a schematic view illustrating an example of the configuration of the transfer robot 1 according to the first embodiment. As illustrated in FIGS. 2 and 3, the transfer robot 1 includes a robot arm 1a, a robot hand 1b, a base portion 1c, a movement device 1d, and a wrist portion 1e. The transfer robot 1 transfers the wafer storage container 200 to each unit by stretching or rotationally moving the robot arm 1a supported by the base portion 1c in a state where the flange 203 is gripped by the robot hand 1b provided at the tip end of the robot arm 1a. FIGS. 2 and 3 omit the illustration of gripping claws provided in the robot hand 1b.

The movement device 1d includes a servo motor and a ball screw mechanism (not illustrated), and may move the base portion 1c in the vertical direction in FIG. 1. That is, the movement device 1d moves the robot arm 1a and the robot hand 1b by moving the base portion 1c.

As illustrated in the example of FIG. 3, the robot arm 1a of the transfer robot 1 includes a rotary support member 1a1, a first arm 1a2, and a second arm 1a3.

In a state where the rotary support member 1a1 is rotatable around an axis extending in the vertical direction (e.g., vertical axis 11), the lower end of the rotary support member 1a1 is supported on the top of the base portion 1c. Further, in a state where the first arm 1a2 is rotatable around an axis extending in the horizontal direction (e.g., horizontal axis 12), the one end portion of the first arm 1a2 is connected to the upper end of the rotary support member 1a1. Further, in a state where the second arm 1a3 is rotatable around a horizontal axis 13, the one end portion of the second arm 1a3 is connected to the other end portion of the first arm 1a2. Further, the wrist portion 1e is connected to the other end portion of the second arm 1a3 in a state of being rotatable around a horizontal axis 15. Further, the robot hand 1b is connected to the tip end of the wrist portion 1e in a state of being rotatable around an axis 14 orthogonal to the horizontal axis 15. With this configuration, the transfer robot 1 may move the robot hand 1b to various positions.

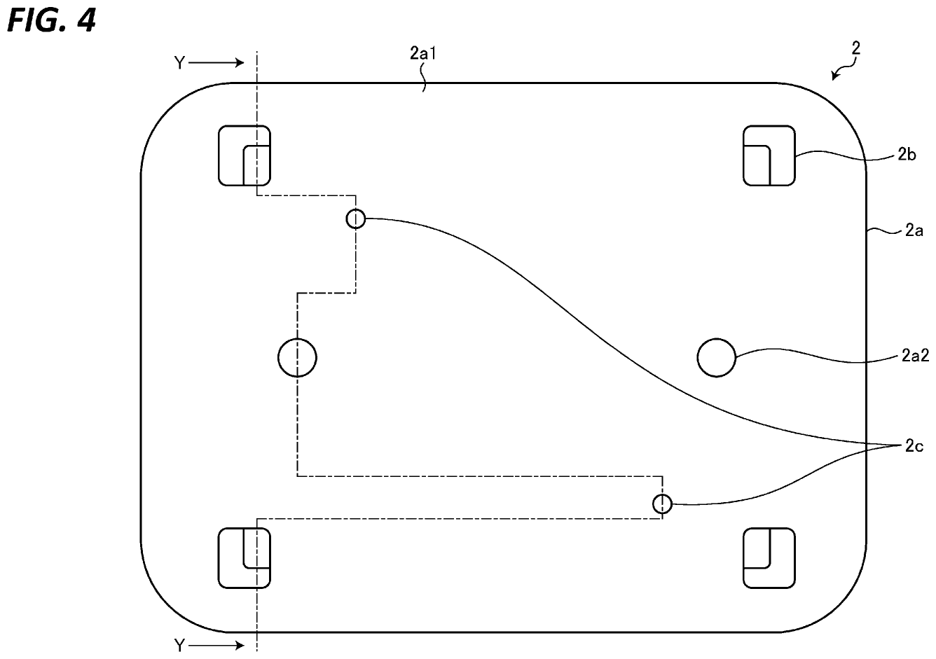

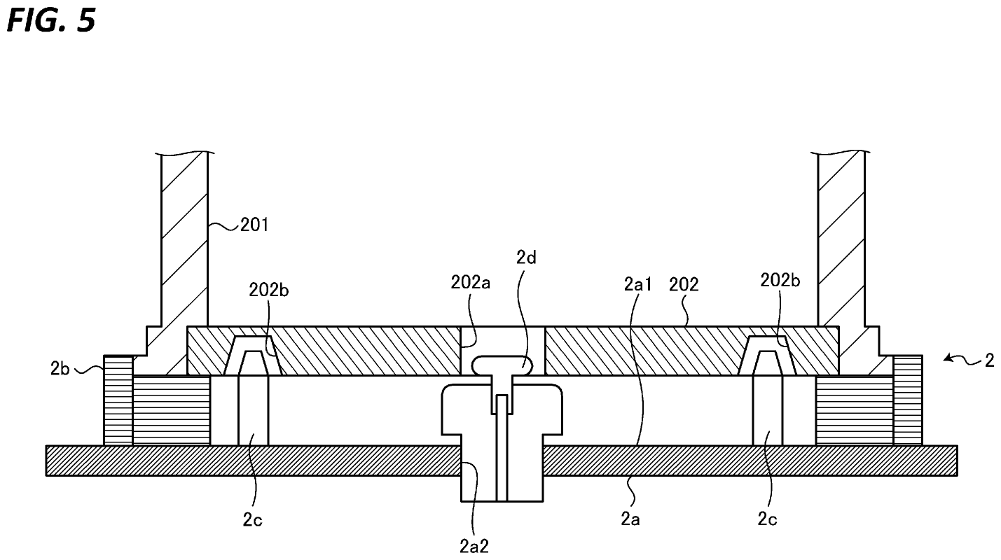

On the lock/unlock stage 2, an unlocking process is performed to disassemble the wafer storage container 200 into the shell 201 and the door 202, and a locking process is performed to connect the shell 201 and the door 202 to each other. FIG. 4 is a plan view illustrating an example of the lock/unlock stage 2 according to the first embodiment. FIG. 5 is a cross-sectional view (side view) taken along the line Y-Y in FIG. 4. FIG. 5 illustrates a state where the door 202 is placed on the placement surface 2a1 of the lock/unlock stage 2, on which the wafer storage container 200 is placed, and FIG. 4 illustrates a state where the door 202 is not placed on the placement surface 2a1 of the lock/unlock stage 2.

As illustrated in FIGS. 4 and 5, the lock/unlock stage 2 includes a substantially rectangular placement table 2a, a plurality of positioning members 2b (e.g., four positioning members 2b), and a plurality of pins 2c (e.g., two pins). The four positioning members 2b are provided at the four corners of a substantially rectangular placement surface 2a1 of the placement table 2a. The positioning members 2b are an example of a positioning aligner. The door 202 (more specifically, the lower surface of the door 202) is placed on the placement surface 2a1. Each positioning member 2b has a step such that each corner of the door 202 aligns with the step when the door 202 is placed on the placement surface 2a1. Therefore, the positioning members 2b may perform the positioning of the door 202 being placed on the placement surface 2a1.

In the center of the placement table 2a, two holes 2a2 are formed. The processes of disassembling/connecting the wafer storage container 200 are performed in the manner that latch keys 2D provided in the placement table 2a rotate in a state of being inserted into the holes 2a2 and also inserted into key holes 202a formed in the door 202. That is, the lock/unlock of the door 202 and the shell 201 is performed in the manner that the latch keys 2d rotate in a state of being inserted into the key holes 202a. Thus, the latch keys 2d are keys not only for connecting the door 202 to the shell 201, but also for removing the door 202 from the shell 201. The size of the door 202 and the positions of the latch keys 2d are specified by the Semiconductor Equipment and Materials International (SEMI) standard. Thus, the positions of the positioning members 2b and the holes 2a2 are determined according to the size of the door 202 and the position of the latch keys 2d. Further, the latch keys 2d are provided to protrude upwardly from the placement surface 2a1 of the placement table 2a, and FIG. 4 omits the illustration of the latch keys 2d.

The pins 2c are provided on the placement surface 2a1 to fit into recesses 202b provided in the door 202. Since the positions of the recesses 202b are specified by the SEMI standard, the pins 2c are provided at positions corresponding to the positions of the recesses 202b.

The wafer storage container 200 carried into the housing 6 is transferred to the lock/unlock stage 2 by the transfer robot 1, and the disassembling process is performed on the lock/unlock stage 2. After the disassembling process is performed on the lock/unlock stage 2, the transfer robot 1 carries the shell 201 and the door 202 separately to the cleaning chamber 3. Further, when a pre-drying of the wafer storage container 200 (a process of blowing off a cleaning liquid to roughly dry the wafer storage container 200) in the cleaning chamber 3 is completed, the transfer robot 1 carries the shell 201 and the door 202 separately out of the cleaning chamber 3, and transfers the shell 201 and the door 202 separately to the vacuum processing chamber 7. Further, the transfer robot 1 transfers the vacuum-dried shell 201 and door 202 to the lock/unlock stage 2, and the connecting process is performed on the lock/unlock stage 2.

In the wafer storage container cleaning apparatus 100 according to the present embodiment, the lock/unlock stage 2 is provided on a plate-shaped support member disposed at a higher position than the installation surface of, for example, the cleaning chamber 3 or the vacuum processing chamber 7.

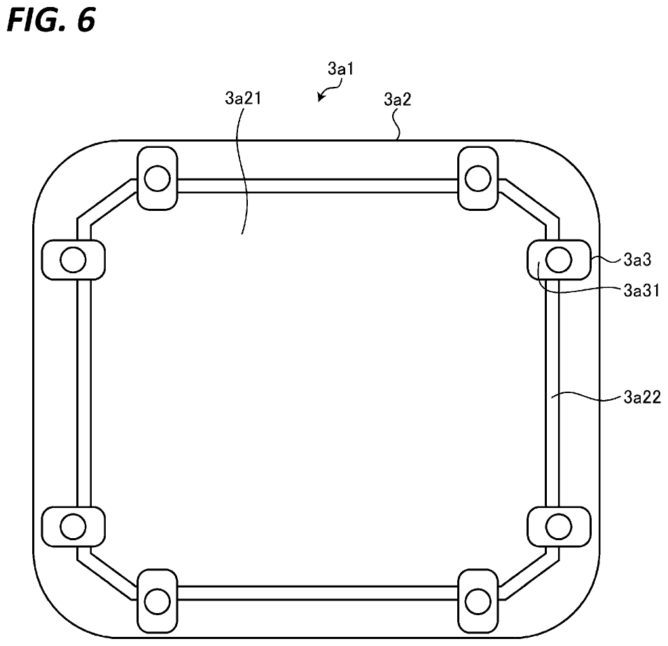

The cleaning chamber 3 is a chamber for cleaning the wafer storage container 200. For example, the shell 201 and the door 202 are transferred separately to the cleaning chamber 3 by the transfer robot 1. Then, the cleaning chamber 3 performs the cleaning process on the wafer storage container 200 in a state of holding the shell 201 and the door 202 separately. For example, as illustrated in FIG. 2, the cleaning chamber 3 includes a cleaning chamber body 3a with an opening at the top surface thereof, a top lid 3b capable of opening/closing the opening of the cleaning chamber body 3a, and a top lid opening/closing drive mechanism 3c that opens/closes the top lid 3b. In the cleaning chamber 3, the top lid 3b holds the door 202, and the shell 201 is placed on the rotary table 3a1 provided in the cleaning chamber body 3a (see, e.g., FIG. 6). Then, in the cleaning chamber 3, the cleaning of the wafer storage container 200 is performed by ejecting the cleaning liquid (e.g., pure water) to each of the shell 201 and the door 202 using a cleaning nozzle provided in the cleaning chamber 3, while rotating the shell 201 and the door 202 by a rotation mechanism (not illustrated). That is, the cleaning chamber 3 includes the rotary table 3a1, which is the placement table, and the cleaning nozzle for cleaning the shell 201 placed on the placement surface of the rotary table 3a1. Further, inside the cleaning chamber 3, for example, the shell 201 is placed such that the opening of the shell 201 faces downward, in consideration of the discharge performance of the cleaning liquid.

When the cleaning of the wafer storage container 200 in the cleaning chamber 3 is completed, the cleaning chamber 3 continues to rotate the shell 201 and the door 202 therein, and blows dry air toward the shell 201 and the door 202 to perform the drying. Here, the drying in the cleaning chamber 3 is a process of roughly drying the cleaning liquid attached to the wafer storage container 200 (e.g., a pre-drying). When the pre-drying of the wafer storage container 200 in the cleaning chamber 3 is completed, the transfer robot 1 transfers the shell 201 and the door 202 in the cleaning chamber 3 separately to the vacuum processing chamber 7.

The wafer storage container cleaning apparatus 100 has four cleaning chambers 3, as illustrated in FIG. 1.

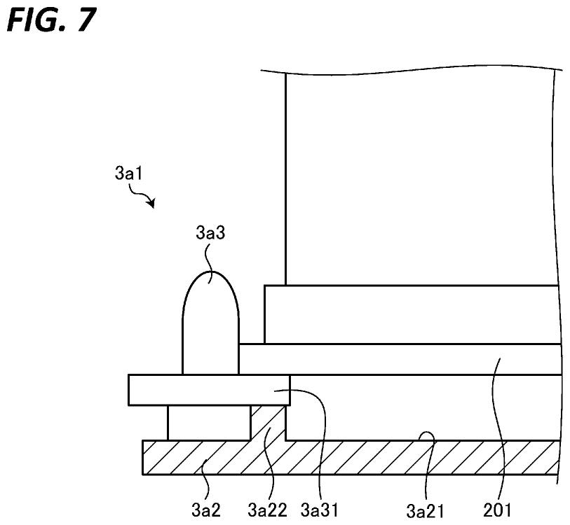

FIG. 6 is a plan view illustrating an example of the rotary table (e.g., the placement table) 3a1 provided in the cleaning chamber 3 according to the first embodiment. FIG. 7 is a view illustrating a portion of the side surface of the rotary table 3a1 according to the first embodiment. Further, FIG. 6 illustrates a state where the shell 201 is not placed on the placement surface 3a21 of the rotary table 3a1 on which the shell 201 (e.g., the placement target surface 201a of the shell 201) is to be placed, and FIG. 7 illustrates a state where the shell 201 is placed on the placement surface 3a21 of the rotary table 3a1.

As illustrated in FIGS. 6 and 7, the rotary table 3a1 includes a substantially rectangular table 3a2 and a plurality of positioning members (positioning pins) 3a3. Two positioning members 3a3 are provided at each of the four corners of the substantially rectangular placement surface 3a21 of the table 3a2. Specifically, a frame 3a22 having a convex shape is provided on the placement surface 3a21, and each positioning member 3a3 is provided to align with the convex shape of the frame 3a22. The positioning member 3a3 is, for example, a positioning pin having a pin shape. The edge portion of the shell 201 is placed on the horizontally extending plate-shaped portion 3a31 of each positioning member 3a3. In this way, the positioning members 3a3 may perform the positioning of the shell 201 being placed on the placement surface 3a21. Further, as described above, the shell 201 is placed on the placement surface 3a21 of the rotary table 3a1 of the cleaning chamber 3 such that the opening of the shell 201 faces downward.

Referring back to FIG. 1, the vacuum processing chamber 7 is a chamber for vacuum-drying the wafer storage container 200 (e.g., a main drying). For example, the vacuum processing chamber 7 includes a vacuum chamber body, an opening/closing lid, a heater, and a decompression device that may evacuate the inside of the vacuum processing chamber 7 (e.g., including an exhaust vent and an exhaust pump). In the vacuum processing chamber 7, the shell 201 and the door 202 are carried into the vacuum chamber body by the transfer robot 1, and in a state where the opening of the vacuum chamber body is closed by the opening/closing lid, the vacuum processing chamber 7 is evacuated by the decompression device and heated by a heater to vacuum-dry the shell 201 and the door 20.

The control unit 8 controls the operation of the entire wafer storage container cleaning apparatus 100. For example, the control unit 8 controls the transfer robot 1, the lock/unlock stage 2, the cleaning chamber 3, the vacuum processing chamber 7, the first carry-in/out port 9a, the second carry-in/out port 9b, and the third carry-in/out port 9c, thereby operating the transfer robot 1, the lock/unlock stage 2, the cleaning chamber 3, the vacuum processing chamber 7, the first carry-in/out port 9a, the second carry-in/out port 9b, and the third carry-in/out port 9c as described above.

For example, the control unit 8 includes a central processing unit (CPU), a read only memory (ROM), a random access memory (RAM), a hard disk drive (HDD), and a communication interface. These components are connected to each other via an internal bus.

The CPU executes various processes by using the memory area of the RAM as a temporary storage area for data used in the various processes. The ROM and the HDD store programs for executing various processes, or various databases and tables used when executing the various processes.

The communication interface is an interface not only for communicating with each unit of the wafer storage container cleaning apparatus 100, but also for communicating with external devices connected to the wafer storage container cleaning apparatus 100 via a network. For example, the communication interface is a network interface card.

The input interface 10 receives an input operation of various instructions and various information from an operator. Specifically, the input interface 10 is connected to the control unit 8, and transmits the input operation received from the operator to the control unit 8. The input interface 10 is, for example, a mouse, a keyboard, or a touch panel.

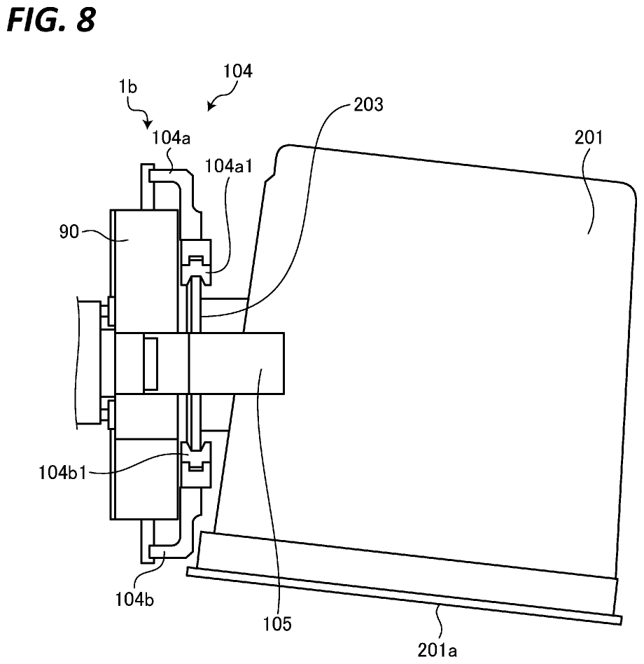

The robot hand 1b according to the present embodiment includes a shell gripping unit 104 having a pair of gripping claws 104a1 and 104b1 gripping the flange 203 of the shell 201, and a door gripping unit 105 having a pair of gripping claws gripping the door 202 (see, e.g., FIG. 8). The opening/closing direction of the gripping claws 104a1 and 104b1 of the shell gripping unit 104 and the opening/closing direction of the pair of gripping claws gripping the door 202 are orthogonal to each other, and the opening/closing operations thereof are performed by a drive unit (not illustrated). The container shell gripping unit 104, the door gripping unit 105, and the drive unit that performs the opening/closing operations of the gripping units are provided in a common base unit 90. The robot hand 1b is an example of a gripping unit. The gripping claws 104a1 and 104b1 are an example of the shell gripping claws, and the door gripping unit 105, which grips the door 202 using the pair of gripping claws, is an example of the door gripping claws.

The sagging of the shell 201 (bending of the flange 203) described above is described more in detail. FIG. 8 is a view illustrating an example of a state where the robot hand 1b according to the first embodiment grips the flange 203 and lifts the shell 201 in the case where a support member 106 to be described herein later is not provided. FIG. 8 illustrates an example of the case where the pair of gripping claws 104a1 and 104b1 grip the flange 203 by pinching the flange 203 in the up and down direction (e.g., a vertical direction).

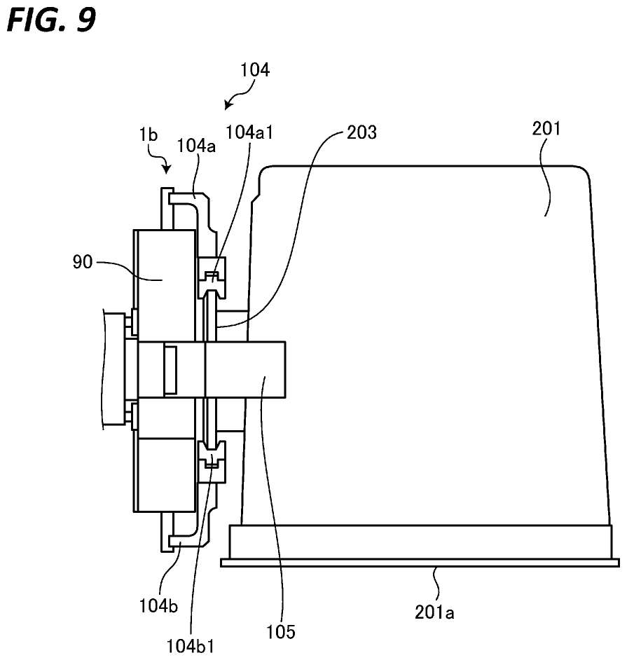

As illustrated in FIG. 8, when the robot hand 1b grips the flange 203 to lift or move the shell 201, a portion of the flange 203 of the shell 201 may bend. In this case, the lower end of the shell 201 (e.g., the placement target surface 201a, e.g., the lower surface of the shell 201 in which the opening is formed) tilts with respect to the horizontal plane. Essentially, the flange 203 should not bend. As illustrated in FIG. 9, the wafer storage container 200 is configured such that in a state where the robot hand 1b does not grip the flange 203 and does not lift the shell 201 so that the weight of the entire shell 201 is not applied to the flange 203, the extending surface of the flange 203 and the placement target surface 201a are orthogonal to each other. Thus, in a state where the flange 203 gripped by the robot hand 1b does not bend, the extending surface of the flange 203 gripped by the gripping claws 104a1 and 104b1 and the placement target surface 201a intersect vertically with each other.

Here, descriptions are made on adverse effects that may occur when the transfer robot 1 transfers the shell 201 to the rotary table 3a1 of the cleaning chamber 3 (see, e.g., FIG. 6) in a state where the placement target surface 201a tilts with respect to the horizontal plane. The transfer robot 1 places the shell 201 on the placement surface 3a21 of the rotary table 3a1 in a state where the placement target surface 201a tilts with respect to the horizontal plane. The placement surface 3a21 is designed to be parallel to the horizontal plane, and the positioning members 3a3 are designed assuming that the shell 201 is placed on the placement surface 3a21 in a state where the placement target surface 201a is parallel to the horizontal plane. Thus, when the shell 201 is carried into the cleaning chamber 3 in a state where the placement target surface 201a tilts with respect to the horizontal plane, for example, the shell 201 may be placed on the positioning members 3a3, or the edge of the shell 201 may be placed outside the positioning members 3a3, and as a result, the shell 201 may not align with the positioning members 3a3. In a state where the shell 201 does not align with the positioning members 3a3, the shell 201 may not be placed at the accurate position while tilting with respect to the placement surface 3a21, or may not be carried into the cleaning chamber 3, for example, since the shell 201 hits the wall surface of the cleaning chamber 3 during the carry-in of the shell 201 into the cleaning chamber 3, which may require measures to stop the process and unload the wafer storage container 200, resulting in the deterioration in process efficiency.

Further, descriptions are made on adverse effects that may occur when the transfer robot 1 transfers the wafer storage container 200 to the placement table 2a of the lock/unlock stage 2 (see, e.g., FIGS. 4 and 5) in a state where the lower surface of the door 202 of the wafer storage container 200 tilts with respect to the horizontal plane. The transfer robot 1 places the wafer storage container 200 on the placement surface 2a1 of the placement table 2a in a state where the lower surface of the door 202 tilts with respect to the horizontal plane. The placement surface 2a1 is designed to be parallel to the horizontal plane, and the positioning members 2b and the pins 2c are designed assuming that the wafer storage container 200 is placed on the placement surface 2a1 in a state where the lower surface of the door 202 is parallel to the horizontal plane. Thus, when the door 202 is transferred to the lock/unlock stage 2 in a state where the placement target surface 201a tilts with respect to the horizontal plane, the door 202 may be placed on the positioning members 2b, and thus, may not align with the positioning members 2b and the pins 2c. In this case, the wafer storage container 200 may not be placed on the placement surface 2a1, and the process may be stopped to unload the wafer storage container 200, which deteriorates the process efficiency.

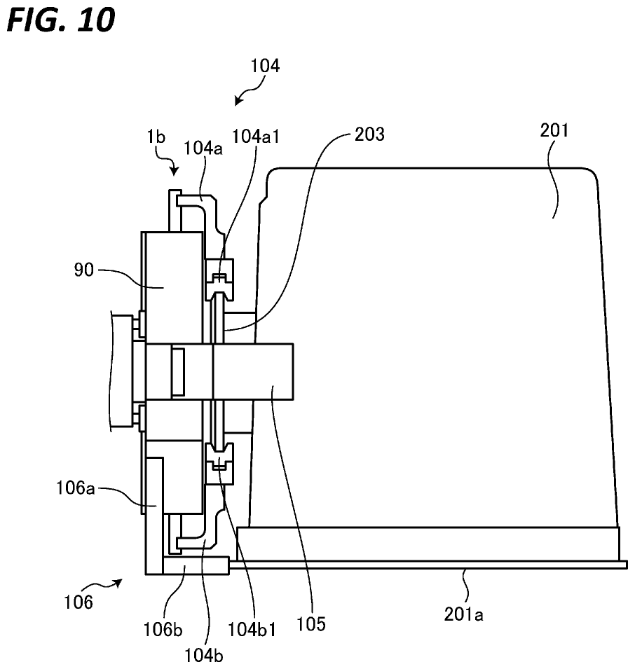

Therefore, as described herein later, in the transfer apparatus and the wafer storage container cleaning apparatus 100 according to the present embodiment, the shell 201 is transferred to the cleaning chamber 3 by the transfer robot 1, in a state where the flange 203 is gripped by the robot hand 1b, and the shell 201 is supported by the support member 106 (see, e.g., FIG. 10) such that the placement target surface 201a becomes parallel to the horizontal plane. Further, as described herein later, in the transfer apparatus and the wafer storage container cleaning apparatus 100 according to the present embodiment, the shell 201 to which the door 202 is connected is transferred to the lock/unlock stage 2 by the transfer robot 201, in a state where the flange 203 is gripped by the robot hand 1b, and the shell 201 to which the door 202 is connected is supported by the support member 106 such that the lower surface of the door 202 becomes parallel to the horizontal plane.

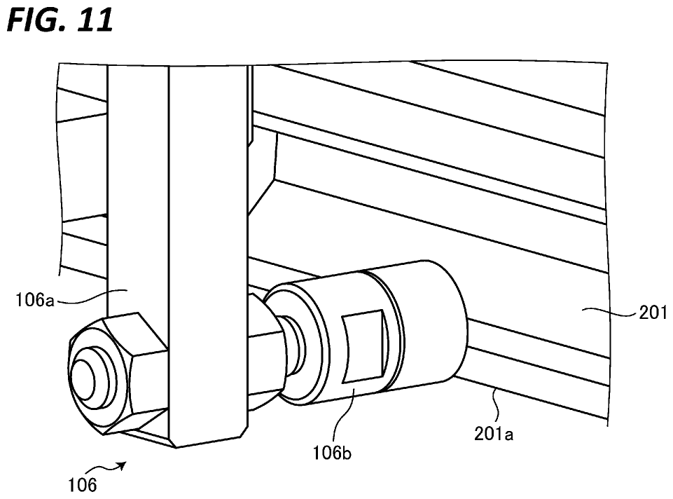

Next, with reference to FIGS. 10 and 11, an example of the configuration of the support member 106 according to the first embodiment is described. FIG. 10 is a side view of an example of the support member 106 according to the first embodiment. FIG. 11 is an enlarged view of the contact portion between the support member 106 and the shell 201 according to the first embodiment.

As illustrated in FIG. 10, the support member 106 is provided on the robot hand 1b, and includes an attachment plate 106a and a support member body 106b. The attachment plate 106a is attached to the base unit 90 of the robot hand 1b, and the support member body 106b is provided on the base unit 90 via the attachment plate 106a. The attachment plate 106a is a flat plate-shaped member that has a conductivity. The attachment plate 106a may be made of a harder material than the shell 201. For example, while the shell 201 is made of polycarbonate, the attachment plate 106a is made of a PEEK material having the conductivity. One end of the attachment plate 106a is attached to the robot hand 1b such that when the flange 203 is gripped by the pair of gripping claws 104a1 and 104b1, the attachment plate 106a extends along the direction following the plane in which the flange 203 extends.

The substantially rod-shaped conductive support member body 106b is attached to the other end of the attachment plate 106a, such that when the flange 203 is gripped by the pair of gripping claws 104a1 and 104b1, the support member body 106b extends along the direction orthogonal to the plane in which the flange 203 extends. That is, the support member body 106b is provided to extend from the robot hand 1b to the side of the shell 201 gripped by the gripping claws 104a1 and 104b1. The support member body 106b may be made of a harder material than the shell 201. For example, the support member body 106b is made of a PEEK material having the conductivity. The length of the support member body 106b is fixed, and the support member body 106b does not slide to change its length. The length from the upper surface of the flange 203 (e.g., the top surface when the flange 203 is held by the OHT) to the top of the opening of the shell 201 is specified by the SEMI standard. The support member 106 (e.g., the support member body 106b) is provided at a position that does not interfere with (e.g., that is not in contact with) the door 202 when the door 202 is gripped by the pair of gripping claws 202 of the door gripping unit 105. Further, in order to make the support member body 106b firmly in contact with the shell 201, the support member 106 may be provided such that the lower end of the support member body 106b is lower than the placement target surface 201a of the shell 201. That is, the support member body 106b may be provided such that the lower end of the support member body 106b is lower than the lower end of the shell 201 in a state where the flange 203 (e.g., the shell 201) is gripped by the pair of gripping claws 104a1 and 104b1. The portion of the support member body 106b in contact with the shell 201 has, for example, a circular shape as illustrated in FIG. 11.

The support member body 106b may be in contact with the shell 201 at a different position from the flange 203. As illustrated in FIG. 10, when the robot hand 1b grips the flange 203 and lifts the shell 201 in a state where the opening of the shell 201 having the placement target surface 201a faces downward, the support member body 106b supports the shell 201 by abutting (contacting) the edge of the opening of the shell 201. That is, the support member body 106b supports the shell 201 such that the placement target surface 201a of the shell 201 becomes horizontal.

Further, when the robot hand 1b grips the flange 203 and lifts the shell 201 in a state where the door 202 is connected to the shell 201, the support member body 106b supports the shell 201 such that the placement target surface 201a of the shell 201 becomes horizontal, so that the lower surface of the door 202 connected to the shell 201 also becomes horizontal. Thus, the support member body 106b supports the shell 201 such that the lower surface of the door 202 connected to the shell 201 becomes horizontal.

The attachment plate 106a and the support member body 106b may be a single integrated member.

As described above, the support member 106 is made of the conductive PEEK material. Accordingly, the electrical charging of the shell 201 may be prevented. As a result, the adhesion of dust to the shell 201 may be prevented.

Next, the function of the support member 106 is described. Here, the function of the support member 106 is described assuming a case where the transfer robot 1 transfers the wafer storage container 200 from the carry-in/out port (the first carry-in/out port 9a, the second carry-in/out port 9b, or the third carry-in/out port 9c) to the lock/unlock stage 2, and a case where the transfer robot 1 transfers the shell 201 from the lock/unlock stage 2 to the cleaning chamber 3.

(When the Shell is Transferred from the Lock/Unlock Stage to the Cleaning Chamber)

First, descriptions are made on the case where the transfer robot 1 transfers the shell 201 from the lock/unlock stage 2 to the cleaning chamber 3. In this case, the support member 106 supports the shell 201 such that the placement target surface 201a of the shell 201 becomes parallel to the placement surface 3a21 of the rotary table 3a1 in a state where the shell 201 is gripped by the robot hand 1b (the flange 203 is gripped by the gripping claws 104a1 and 104b1). Then, the transfer robot 1 transfers the shell 201 to the rotary table 3a1 in a state where the flange 203 is gripped by the gripping claws 104a1 and 104b1, and the shell 201 is supported by the support member 106 as described above.

Accordingly, when the transfer robot 1 places the shell 201 on the placement surface 3a21 of the table 3a2, the shell 201 aligns with the positioning members 3a3. In this way, the support member 106 is provided to support the shell 201 such that in a state where the flange 203 is gripped by the gripping claws 104a1 and 104b1, and the placement target surface 201a of the shell 201 faces downward, the placement target surface 201a of the shell 201, before being placed on the placement surface 3a21, has the posture placeable on the placement surface 3a21 of the rotary table 3a1 via the positioning members 3a3. Therefore, the transfer apparatus and the wafer storage container cleaning apparatus 100 may continue the process without stopping the process. As a result, the transfer apparatus and the wafer storage container cleaning apparatus 100 according to the first embodiment may efficiently perform the process.

(When the Wafer Storage Container is Transferred from the Carry-In/Out Port to the Lock/Unlock Stage)

Next, descriptions are made on the case where the transfer robot 1 transfers the shell 201, to which the door 202 is connected, from the carry-in/out port to the lock/unlock stage 2. In this case, the support member 106 supports the shell 201 such that in a state where the flange 203 of the shell 201 to which the door 202 is connected is gripped by the gripping claws 104a1 and 104b1 of the robot hand 1b, the lower surface of the door 202 becomes parallel to the placement surface 2a1 of the placement table 2a. Here, the lower surface of the door 202 is a placement target surface to be placed on the placement surface 2a1 of the placement table 2a.

Accordingly, when the transfer robot 1 places the wafer storage container 200 on the placement surface 2a1 of the placement table 2a, the door 202 aligns with the positioning members 2b and the pins 2c. In this way, the support member 106 is provided to support the shell 201 such that in a state where the flange 203 is gripped by the gripping claws 104a1 and 104b1, and the placement target surface 201a of the shell 201 faces downward, the lower surface of the door 202 connected to the shell 201, before being placed on the placement surface 2a1, has the posture placeable on the placement surface 2a1 of the placement table 2a via the positioning members 2b and the pins 2c. Therefore, the transfer apparatus and the wafer storage container cleaning apparatus 100 may continue the process without stopping the process. As a result, the transfer apparatus and the wafer storage container cleaning apparatus 100 according to the first embodiment may efficiently perform the process.

In the embodiment described above, the placement surface (the placement surface 2a1 and the rotary table 3a1) are provided horizontally, and the support member 106 supports the shell 201 such that the placement target surface 201a and the lower surface of the door 202 are held in parallel to the horizontal plane during the transfer of the shell 201 and the door 202. However, the present disclosure is not limited thereto. The placement surface may not necessarily be provided to be parallel to the horizontal plane, but may be, for example, inclined. In this case, the support member 106 may support the shell 201 such that the placement target surface 201a and the lower surface of the door 202 are held in parallel to the placement surface during the transfer of the shell 201 and the door 202, according to the inclination angle of the placement surface with respect to the horizontal plane.

In the embodiment described above, the support member body 106b does not include a length adjustment mechanism. However, the present disclosure is not limited thereto. For example, the support member body 106b may include a length adjustment mechanism to change its length according to the type of wafer storage container.

In the embodiment described above, the length of the support member body 106b is the length in which the placement target surface 201a of the shell 201 becomes parallel to the placement table with its placement surface designed to be horizontal. However, the present disclosure is not limited thereto. The placement surface of the placement table may not necessarily be designed to be horizontal as long as the shell 201 may be placed on the placement surface. The length of the support member body 106b may be any length as long as the posture of the shell 201 may be corrected such that the placement target surface 201a becomes placeable on the placement surface, when the shell 201 is gripped and lifted by the robot hand 1b via the flange 203. Alternatively, the length of the support member body 106b may be any length as long as the change of the posture of the shell 201 caused from the dislocation of the shell 201 near the flange 203 may be suppressed, when the shell 201 is gripped and lifted by the robot hand 1b via the flange 203. Further, the length of the support member body 106b may be set to the length in which the support member 106b is not in contact the shell 201 in the case where the shell 201 has the posture placeable on the placement surface when being gripped by the robot hand 1b via the flange 203. Further, the length of the attachment plate 106a may be adjustable. By adjusting the length of the attachment plate 106a, the height position of the support member body 106b (in the vertical direction in FIG. 10) may be changed.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A transfer apparatus comprising:
a transfer robot configured to transfer a shell of a wafer storage container to a placement table including a positioning aligner,
wherein the transfer robot includes
a robot hand configured to grip the shell,
the robot hand includes a pair of shell gripping claws that grips a flange of the shell, and a support contactable with the shell at a different position from the flange,
a placement target surface of the shell crosses a surface of the shell on which the flange is provided,
the support is provided to support the shell such that in a state where the flange is gripped by the shell gripping claws, and the placement target surface of the shell faces downward, the placement target surface of the shell, before being placed on a placement surface of the placement table, has a posture placeable on the placement surface of the placement table via the positioning aligner, and
the transfer robot transfers the shell to the placement table in a state where the flange is gripped by the shell gripping claws, and the shell is supported by the support.

2. The transfer apparatus according to claim 1, wherein the robot hand further includes a pair of door gripping claws that grips a door of the wafer storage container,
the support is provided in the robot hand to not be in contact with the door in a state where the door is gripped by the door gripping claws, and to be in contact with the shell thereby supporting the shell in a state where the flange of the shell is gripped by the shell gripping claws.

3. The transfer apparatus according to claim 1, wherein the support supports the shell by being in contact with an edge of an opening of the shell, which has the placement target surface.

4. The transfer apparatus according to claim 1, wherein the support is provided such that, in a state where the shell is gripped by the shell gripping claws, a lower end of the support is positioned lower than a lower end of the shell.

5. The transfer apparatus according to claim 3, wherein the support includes an attachment plate and a support body attached to the robot hand via the attachment plate and extending from the robot hand toward the shell gripped by the shell gripping claws, and
the support body has a length in which the support body is not in contact with the shell in a case where the placement target surface has the posture placeable on the placement table when the shell is gripped and lifted by the shell gripping claws.

6. A wafer storage container cleaning apparatus comprising:
the transfer apparatus according to claim 1; and
a cleaning chamber including the placement table, and a cleaning nozzle that cleans the shell in a state where the shell is placed on the placement surface of the placement table.
